(19) United States
(12) Patent Application Publication
(10) Pub. No.: US 2024/0128136 A1
(43) Pub. Date: Apr. 18, 2024

(54) WAFER LEVEL PACKAGE AND METHOD OF MANUFACTURING THE SAME

(71) Applicant: SAMSUNG ELECTRO-MECHANICS CO., LTD., Suwon-si (KR)

(72) Inventors: Seung Wook PARK, Suwon-si (KR); Seong Hun NA, Suwon-si (KR); Jae Hyun JUNG, Suwon-si (KR); Kwang Su KIM, Suwon-si (KR); Sung Jun LEE, Suwon-si (KR); Yong Suk KIM, Suwon-si (KR); Dong Hyun PARK, Suwon-si (KR)

(73) Assignee: SAMSUNG ELECTRO-MECHANICS CO., LTD., Suwon-si (KR)

(21) Appl. No.: 18/110,478

(22) Filed: Feb. 16, 2023

(30) Foreign Application Priority Data
Oct. 14, 2022 (KR) 10-2022-0132414

(51) Int. Cl. H01L 23/10; H01L 21/48; H01L 23/043

(52) U.S. Cl. CPC H01L 23/10; H01L 21/4817; H01L 23/043

(57) ABSTRACT

A wafer level package includes: a substrate; an element portion disposed on one surface of the substrate; a cap disposed on the substrate to cover the element portion; a connection portion electrically connected to the element portion; and a bonding portion disposed on an outer side of the connection portion, wherein the bonding portion is disposed on a first surface of one of the substrate and the cap, wherein one end portion of the connection portion is disposed on a second surface having a step difference from the first surface, and wherein the connection portion and the bonding portion are formed of a eutectic material.

### CROSS-REFERENCE TO RELATED APPLICATION(S)

This application claims the benefit under 35 USC 119(a) of Korean Patent Application No. 10-2022-0132414 filed on Oct. 14, 2022, in the Korean Intellectual Property Office, the entire disclosure of which is incorporated herein by reference in its entirety for all purposes.

### BACKGROUND

### 1. Field

The present disclosure relates to a wafer level package and a method of manufacturing the same.

### 2. Description of the Background

In general, a metal bonding in surface acoustic wave (SAW), bulk acoustic wave (BAW), and micro-electro-mechanical systems (MEMS) packages is a significantly attractive hermetic means. However, a gold-to-gold (Au-to-Au) bonding package may incur high costs, so that it is necessary to develop a metal bonding package to replace the Au-to-Au bonding package.

A hermetic package using tin (Sn) is a general-purpose technology. However, on a wafer level, the hermetic package requires a structure for flow suppression, such as a trench and a dam, due to an effect of a flow of tin (Sn). Accordingly, there is an issue in miniaturization of a package.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a wafer level package includes: a substrate; an element portion disposed on one surface of the substrate; a cap disposed on the substrate to cover the element portion; a connection portion electrically connected to the element portion; and a bonding portion disposed on an outer side of the connection portion, wherein the bonding portion is disposed on a first surface of one of the substrate and the cap, wherein one end portion of the connection portion is disposed on a second surface having a step difference from the first surface, and wherein the connection portion and the bonding portion are formed of a eutectic material.

The first surface and the second surface may be disposed on the cap, the first surface may be disposed on a lower surface of the cap, and the second surface may be disposed on a stepped groove disposed in the cap.

The stepped groove may be connected to a through-silicon via (TSV) disposed in the cap.

The wafer level package may further include: an external connection terminal disposed on an upper surface of the cap and electrically connected to the connection portion; and a passivation layer disposed to cover a redistribution layer, wherein the external connection terminal and the connection portion may be connected to each other by the redistribution layer.

The connection portion and the bonding portion may include gold-tin (Au—Sn), copper-tin (Cu—Sn), or aluminum-germanium (Al—Ge), respectively.

The cap may include a flow suppression groove disposed between the bonding portion and the connection portion.

The connection portion may include a single column or a plurality of columns.

The cap may include a groove portion disposed over the element portion.

The first surface and the second surface may be disposed on the substrate, the first surface may be disposed on an upper surface of the substrate, and the second surface may be disposed on a stepped groove disposed in the substrate.

A through-silicon via (TSV) may be disposed in the cap to be disposed over the stepped groove.

The stepped groove may be disposed in a first metal pad disposed on the substrate.

In another general aspect, a method of manufacturing a wafer level package includes: forming a connection portion and a bonding portion on a lower surface of a cap to be spaced apart from each other; aligning a substrate, having an upper surface on which an element portion is formed, and the cap with each other; and bonding the substrate and the cap to each other via the bonding portion, wherein when the substrate and the cap are bonded to each other, a pressure applied to the bonding portion is higher than a pressure applied to the connection portion.

The connection portion may have one end portion disposed to be inserted into a stepped groove formed in the cap and the bonding portion may be formed on a first surface disposed around the stepped groove.

The connection portion may be bonded to a first metal pad formed on an upper surface of the substrate and the bonding portion may be bonded to a second metal pad having an upper surface disposed on a same plane as an upper surface of the first metal pad.

The connection portion may have one end portion disposed to be inserted into a stepped groove formed in the first metal pad of the substrate and the bonding portion may be formed on an upper surface of a second metal pad having a height difference by a depth of the stepped groove.

A thickness of the connection portion may be smaller than a thickness of the bonding portion.

The connection portion and the bonding portion may be formed on a lower planar surface of the cap and an upper planar surface of the substrate, and may be bonded to upper surfaces of the first and second metal pads, wherein the upper surfaces of the first and second metal pads may be disposed in a same plane.

The connection portion and the bonding portion may include gold-tin (Au—Sn), copper-tin (Cu—Sn), or aluminum-germanium (Al—Ge), respectively.

In still another general aspect, a wafer level package includes: a substrate; an element portion disposed on one surface of the substrate; a cap disposed on the substrate to cover the element portion; a connection portion electrically connected to the element portion; and a bonding portion disposed to surround the connection portion, wherein the bonding portion is disposed on a first surface of one of the substrate and the cap, wherein one end portion of the connection portion is disposed on a second surface, which is recessed from the first surface, and wherein the connection portion and the bonding portion are formed of a eutectic material.

The second surface may be connected to a through-silicon via (TSV) disposed in the cap.

Other features and aspects will be apparent from the following detailed description, the drawings, and the claims.

### BRIEF DESCRIPTION OF DRAWINGS

FIG. 1 is a schematic cross-sectional view of a wafer level package according to an embodiment of the present disclosure.

FIG. 2 is an enlarged view of portion “A” of FIG. 1.

FIGS. 3 to 14 are process views illustrating a method of manufacturing a wafer level package according to an example.

FIGS. 15 to 18 are process views illustrating a method of manufacturing a wafer level package according to an example.

FIGS. 19 to 22 are process views illustrating a method of manufacturing a wafer level package according to an example.

FIGS. 23 to 26 are process views illustrating a method of manufacturing a wafer level package according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items; likewise, “at least one of” includes any one and any combination of any two or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present description. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, various embodiments will be described with reference to schematic views. In the drawings, for example, due to manufacturing techniques and/or tolerances, modifications of the shape shown may be estimated. Thus, the following description should not be construed as being limited to the shapes of regions shown herein, and, for example, be understood to include a change in shape results in manufacturing. The following embodiments may also be constituted by one or a combination thereof.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

An aspect of the present disclosure is to provide a waver level package for implementing miniaturization of a package by reducing an effect caused by a flow of tin (Sn) and a method of manufacturing the same.

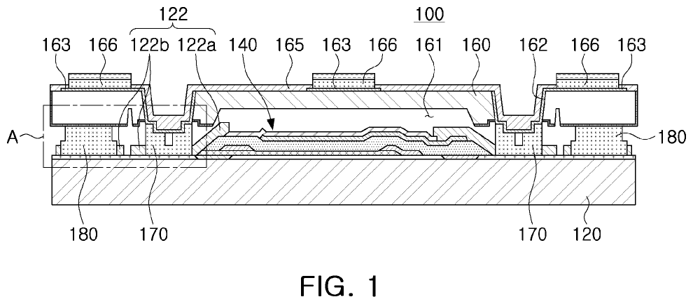

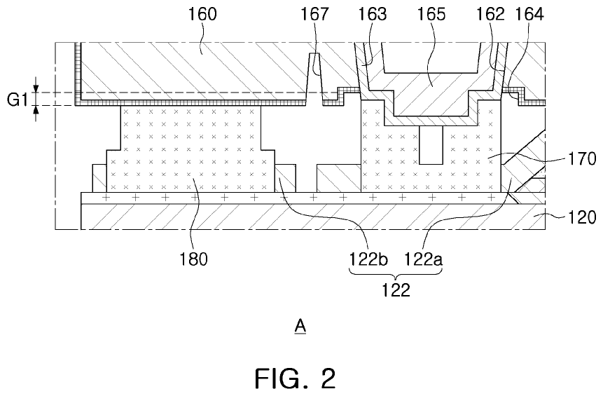

FIG. 1 is a schematic cross-sectional view of a wafer level package according to an embodiment of the disclosure, and FIG. 2 is an enlarged view of portion “A” of FIG. 1.

Referring to FIGS. 1 and 2, a wafer level package 100 according to an embodiment may include a substrate 120, an element portion 140, and a cap 160.

The substrate 120 may be bonded to the cap 160, and a space may be formed between the substrate 120 and the cap 160. The element portion 140 may be disposed on one surface of the substrate 120. The substrate 120 may be a silicon substrate. For example, a silicon wafer or a silicon-on-insulator (SOI) substrate may be used as the substrate 120.

The substrate 120 may include a metal pad 122 contacting a connection portion 170 and a bonding portion 180 to be described later. The metal pad 122 may include a first metal pad 122a, connected to the connection portion 170, and a second metal pad 122b connected to the bonding portion 180. The first metal pad 122a may be connected to an electrode, not illustrated, of the element portion 140. The second metal pad 122b may be spaced apart from the first metal pad 122a to be electrically separated from the first metal pad 122a. The first metal pad 122a and the second metal pad 122b may be disposed on the same plane. As an example, upper surfaces of the first metal pad 122a and the second metal pad 122b may be disposed at the same height from an upper surface of the substrate 120. For example, the first metal pad 122a and the second metal pad 122b may be formed of a gold (Au) material.

The element portion 140 may be disposed on the upper surface of the substrate 120. As an example, the element portion 140 may be a bulk acoustic wave (BAW) resonator. However, examples are not limited thereto and the element portion 140 may be a micro-electro-mechanical systems (MEMS) resonator or a surface acoustic wave (SAW) resonator. The element portion 140 may include a resonant portion including a first electrode, a piezoelectric layer, and a second electrode, and a cavity may be disposed below the resonant portion. An etch-stop layer disposed to surround the cavity and a sacrificial layer disposed on an outer side of the etch-stop layer may be disposed on the upper surface of the substrate 120.

The cap 160 may include a groove portion 161 disposed on the element portion 140. A through-silicon via (TSV) 162 may be disposed around the groove portion 161. The TSV 162 may be disposed to penetrate through the cap 160, and a redistribution layer 163 may be disposed in the TSV 162. The redistribution layer 163 may extend from the TSV 162 to an upper surface of the cap 160. A stepped groove 164 disposed to surround the TSV 162 may be provided on a lower surface of the cap 160 and may be formed to be recessed into the lower surface of the cap 160. For example, the stepped groove 164 and the lower surface of the cap 160 may form a height difference G1 of a predetermined distance. For example, when the lower surface of the cap 160 is referred to as a first surface and a ceiling surface of the stepped groove 164 having a step difference with the first surface is referred to as a second surface, the first surface and the second surface may have the height difference G1 of the predetermined distance. Accordingly, a distance between the second surface and the upper surface of the substrate 160 may be greater than a distance between the first surface and the upper surface of the substrate 160. For example, a distance between the second surface and the first metal pad 122a disposed on the upper surface of the substrate 160 may be greater than a distance between the first surface and the second metal pad 122b.

A connection portion 170 may be disposed in a space between the stepped groove 164 of the cap 160 and the upper surface of the first metal pad 122a. For example, the connection portion 170 may be disposed to contact the second surface, the ceiling surface of the stepped groove 164, and the upper surface of the first metal pad 122a. In addition, the connection portion 170 may include a eutectic material. As an example, the connection portion 170 may include one of gold-tin (Au—Sn), copper-tin (Cu—Sn), or aluminum-germanium (Al—Ge). In the present example, a description will be provided for a case, in which the connection portion 170 is a eutectic material including gold-tin (Au—Sn).

A bonding portion 180 may be disposed around the connection portion 170 to surround the connection portion 170. In addition, the bonding portion 180 may include a eutectic material. As an example, the bonding portion 180 may include one of gold-tin (Au—Sn), copper-tin (Cu— Sn), or aluminum-germanium (Al—Ge). In the present example, a description will be provided for a case, in which the bonding portion 180 is a eutectic material including gold-tin (Au—Sn). The bonding portion 180 may be disposed between the lower surface of the cap 160 and an upper surface of the second metal pad 122b, and may constitute a hermetic seal while bonding the cap 160 and the substrate 160 to each other.

As described above, the connection portion 170 may be disposed in a space between the stepped groove 164 of the cap 160 and the top surface of the first metal pad 122a. Since the bonding portion 180 is disposed between the first surface of the cap 160 and the upper surface of the substrate 160, a flow of tin (SN) included in the connection portion 170 may be prevented. For example, the second surface of the stepped groove 164 and the first surface, the lower surface of the cap 160, form the height difference G1 of the predetermined distance, so that the connection portion 170 disposed in the stepped groove 164 may be pressurized at a lower pressure than the bonding portion 180 disposed on the lower surface of the cap 160 in a manufacturing process to suppress the flow of tin (Sn) included in the connection portion 170. Accordingly, components (for example, a trench and a dam) for preventing the flow of tin (Sn) included in the connection portion 170 may not be necessary, so that a miniaturization of the wafer level package 100 may be possible.

A trench 167 may be provided in the cap 160 to be disposed between the connection portion 170 and the bonding portion 180. Accordingly, even when tin (Sn) included in the bonding portion 180 flows during a manufacturing process, the bonding portion 180 may be prevented from flowing toward the stepped groove 164.

The cap 160 may be provided with a passivation layer 165 disposed to cover at least the redistribution layer 163, and an external connection terminal 166 electrically connected to the redistribution layer 163 may be disposed on the upper surface of the cap 160.

As described above, one end portion of the connection portion 170 is disposed in the stepped groove 164 of the cap 160, so that a pressure applied to the connection portion 170 during a manufacturing process may be reduced. Accordingly, the flow of tin (Sn) included in the connection portion 170 may be suppressed, so that components for suppressing the flow of tin (Sn), such as a trench and a dam, may not be necessary. Accordingly, miniaturization of the wafer level package 100 may be achieved.

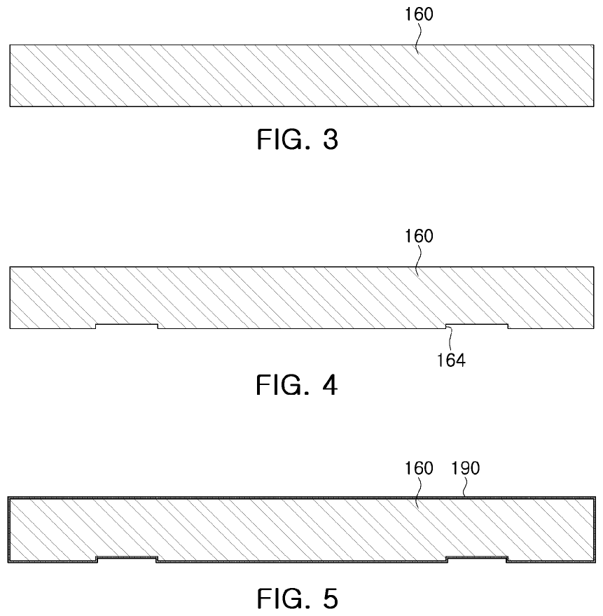

FIGS. 3 to 14 are process views illustrating a method of manufacturing a wafer level package according to one embodiment.

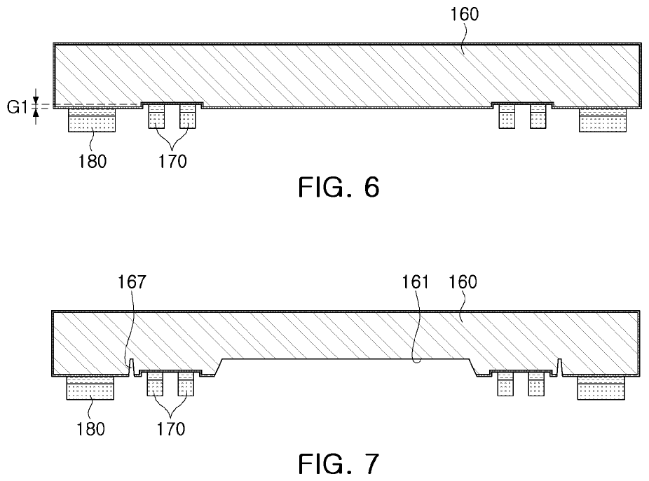

As illustrated in FIG. 3, a cap 160 may be prepared. As illustrated in FIG. 4, a stepped groove 164 may be formed in the cap 160. As illustrated in FIG. 5, an oxide layer 190 may be formed on the cap 160. As illustrated in FIG. 6, the connection portion 170 may be formed such that one end is disposed in the stepped groove 154, and the bonding portion 180 may be formed to be disposed on an outer side of the stepped groove 154. As an example, a plurality of connection portions 170 may be formed to be spaced apart from each other. As illustrated in FIG. 6, the connection portion 170 may be disposed to form two layers, and may include layers formed of gold (Au) and tin (Sn). An overlying layer may be formed of gold (Au), and an underlying layer may be formed of tin (Sn). The bonding portion 180 may also be disposed to form two layers, and may include layers formed of gold (Au) and tin (Sn). An overlying layer may be formed of gold (Au), and an underlying layer may be formed of tin (Sn). However, examples are not limited thereto, and the connection portion 170 and the bonding portion 180 may be formed of one of copper-tin (Cu—Sn) and aluminum-germanium (Al—Ge). As illustrated in FIG. 6, a lower surface of the connection portion 170 may be disposed to be higher than a lower surface of the bonding portion 180, and the lower surface of the connection portion 170 and the lower surface of the bonding portion 180 may form a height difference G1 by a depth of the stepped groove 164. As illustrated in FIG. 7, a groove portion 161 and a trench 167 may be formed in the cap 160. The groove portion 161 may be disposed on an internal side of the connection portion 170, and the trench 167 may be disposed between the connection portion 170 and the bonding portion 180.

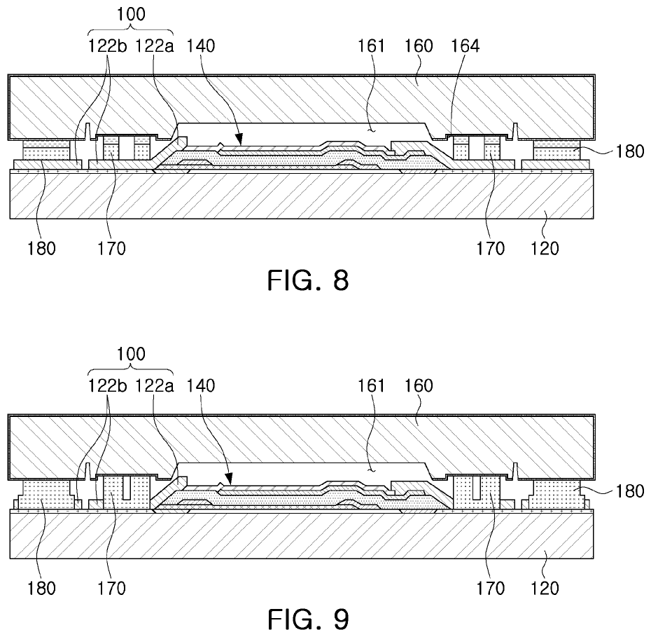

As illustrated in FIG. 8, the cap 160 and the substrate 120 may be aligned with each other. In this case, the element portion 140 may be disposed below the groove 161 of the cap 160, and the first metal pad 122a may be disposed below the connection portion 170. In addition, a second metal pad 122b may be disposed below the bonding portion 180. As illustrated in FIG. 9, the cap 160 and the substrate 120 are bonded to each other. In this case, the cap 160 and the substrate 120 may be bonded by applying heat and pressure. As described above, the lower surface of the connection portion 170 may be higher than the lower surface of the connection portion 180, and the lower surface of the connection portion 170 and the lower surface of the connection portion 180 may form a height difference G1 by a depth of the stepped groove 164. Accordingly, when pressure is applied to bond the cap 160 and the substrate 120 to each other, the pressure applied to the connection portion 170 may be lower than the pressure applied to the bonding portion 180. Accordingly, a flow of the tin (Sn) layer constituting the connection portion 170 may be suppressed. Thus, components such as a trench and a dam to prevent the tin layer constituting the connection portion 170 from flowing toward the element portion 140 may not be necessary. For example, the components such as a trench and a dam to prevent the tin layer from flowing toward the element portion 140 may not be formed between the connection portion 170 and the element portion 140.

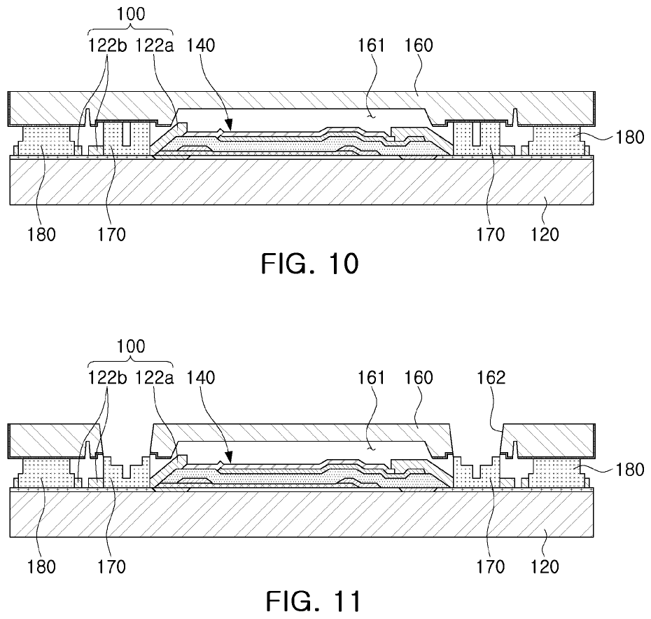

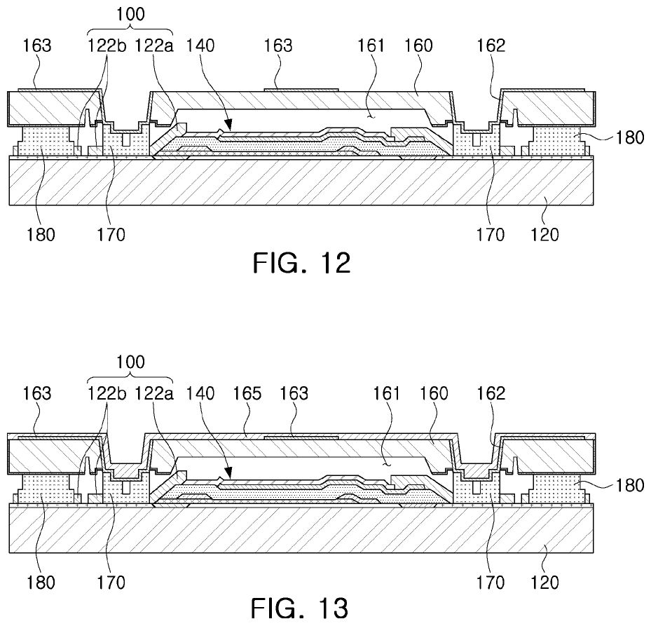

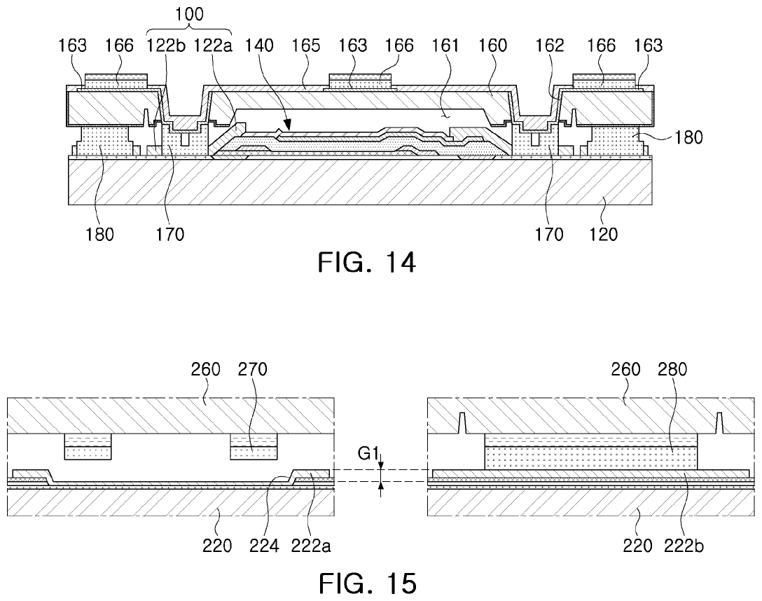

As illustrated in FIG. 10, an upper end of the cap 160 may be removed to reduce a thickness of the cap 160. As illustrated in FIG. 11, a through-silicon via (TSV) 162 may be formed in the cap 160 by etching to be opened to the stepped groove 164. As illustrated in FIG. 12, a redistribution layer 163 may be formed on an upper surface of the cap 160 and an internal surface of the TSV 162. As illustrated in FIG. 13, a passivation layer 165 may be formed. Finally, as illustrated in FIG. 14, an external connection terminal 166 may be formed to be connected to the redistribution layer 163.

As described above, the flow of the tin layer constituting the connection portion 170 may be suppressed by setting the pressure, applied when the substrate 120 and the cap 160 are bonded to each other, to be lower than the pressure applied to the bonding portion 180 in the connection portion 170. Accordingly, the components for suppressing the flow of the tin layer constituting the connection portion 170 may not be necessary, so that miniaturization of the wafer level package 100 may be achieved.

FIGS. 15 to 18 are process views illustrating a method of manufacturing a wafer level package according to one embodiment.

As illustrated in FIG. 15, a connection portion 270 and a bonding portion 280 may be formed on a cap 260. A lower surface of the cap 260 may have a planar surface. Accordingly, a lower surface of the connection portion 270 and a lower surface of the bonding portion 280 may be disposed on the same plane. The connection portion 270 and the bonding portion 280 may have the same thickness. The connection portion 270 may be formed to include two layers, and may include layers formed of gold (Au) and tin (Sn). An overlying layer may be formed of gold (Au), and an underlying layer may be formed of tin (Sn). The bonding portion 280 may also be formed to include two layers, and may include layers formed of gold (Au) and tin (Sn). An overlying layer may be formed of gold (Au), and an underlying layer may be formed of tin (Sn). However, examples are not limited thereto, and the connection portion 270 and the bonding portion 280 may be formed of one of copper-tin (Cu—Sn) and aluminum-germanium (Al—Ge). The connection portion 270 may include a plurality of columns. As an example, the connection portion 270 may include two columns. A stepped groove 224 may be formed in the substrate 220. For example, a height difference G1 may be formed between an upper surface of the first metal pad 222a, disposed below the connection portion 270, and an upper surface of the second metal pad 222b disposed below the bonding portion 280. For example, when the upper surface of the first metal pad 222a is referred to as a first surface and the lower surface of the stepped groove 224 of the second metal pad 222b is referred to as a second surface, the first and second surfaces may have a step difference and may form a height difference G1.

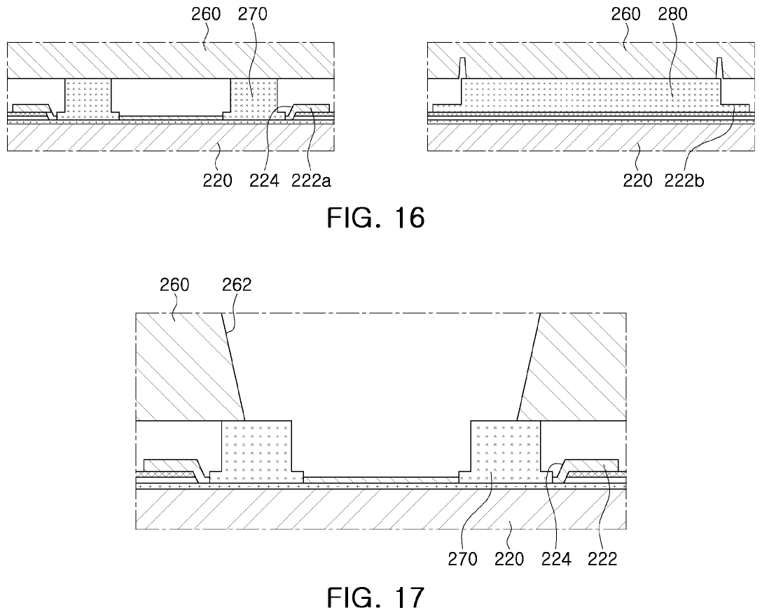

As illustrated in FIG. 16, when the substrate 220 and the cap 260 are bonded to each other, the pressure applied to the connection portion 270 may be lower than the pressure applied to the bonding portion 280. Accordingly, the flow of the tin (Sn) layer constituting the connection portion 270 may be suppressed. Therefore, components such as a trench and a dam to prevent the tin layer constituting the connection portion 270 from flowing toward the element portion 140 (see FIG. 1) may not be necessary. For example, the components such as a trench and a dam to prevent the tin layer from flowing toward the element portion 140 may not be formed between the connection portion 270 and the element portion 140.

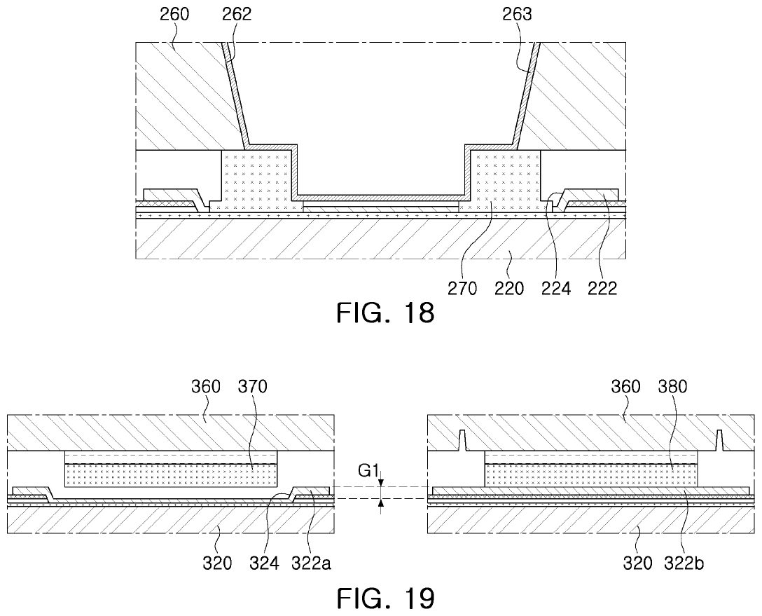

As illustrated in FIG. 17, a TSV 262 may be formed in the cap 260. As illustrated in FIG. 18, a redistribution layer 263 may be formed to extend from an internal surface of the TSV 262 to an upper surface of the cap 260.

As described above, the stepped groove 224 is formed in the substrate 220 to reduce the pressure applied to the connection portion 270, so that the flow of the tin (Sn) layer constituting the connection portion 270 may be suppressed.

FIGS. 19 to 22 are process views illustrating a method of manufacturing a wafer level package according to one embodiment.

As illustrated in FIG. 19, a connection portion 370 and a bonding portion 380 may be formed on a cap 360. A lower surface of the cap 360 may have a planar surface. Accordingly, a lower surface of the connection portion 370 and a lower surface of the bonding portion 380 may be disposed on the same plane. The connection portion 370 and the bonding portion 380 may have the same height. The connection portion 370 may include two layers, and may include layers formed of gold (Au) and tin (Sn). An overlying layer may be formed of gold (Au), and an underlying layer may be formed of tin (Sn). The bonding portion 380 may also include two layers, and may include layers formed of gold (Au) and tin (Sn). An overlying disposed on the upper portion may be formed of a gold (Au) layer, and an underlying layer may be formed of tin (Sn). However, examples are not limited thereto, and the connection portion 370 and the bonding portion 380 may be formed of one of copper-tin (Cu—Sn) and aluminum-germanium (Al—Ge). The connection portion 370 and the bonding portion 380 may include a single column. A stepped groove 324 may be formed in the substrate 320. For example, a height difference G1 may be formed between an upper surface of a first metal pad 322a, disposed below the connection portion 370, and an upper surface of a second metal pad 322b disposed below the bonding portion 380.

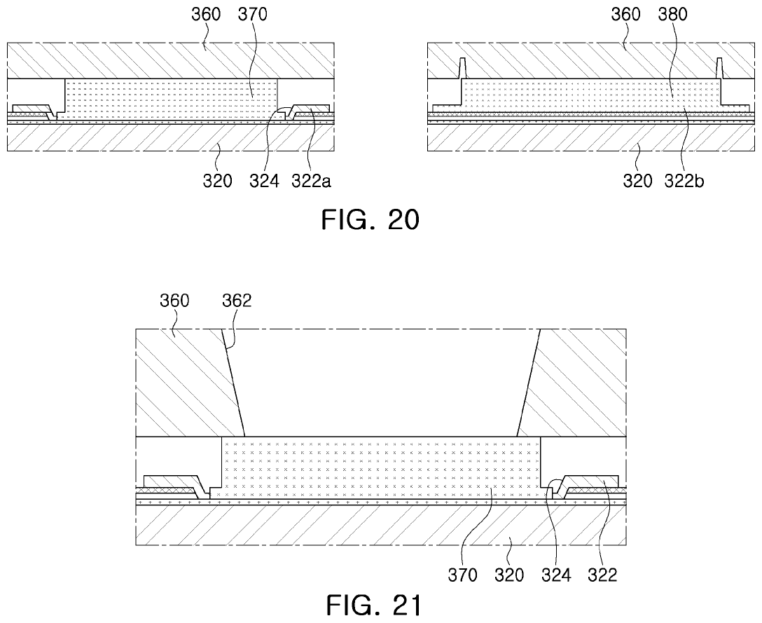

As illustrated in FIG. 20, when the substrate 320 and the cap 360 are bonded to each other, pressure applied to the connection portion 370 may be lower than pressure applied to the bonding portion 380. Accordingly, a flow of the tin (Sn) layer constituting the connection portion 370 may be suppressed. Therefore, components such as a trench and a dam to prevent the tin layer constituting the connection portion 370 from flowing toward an element portion 140 (see FIG. 1) may not be necessary. For example, the components such as a trench and a dam to prevent the tin layer from flowing toward the element portion 140 may not be formed between the connection portion 370 and the element portion 140.

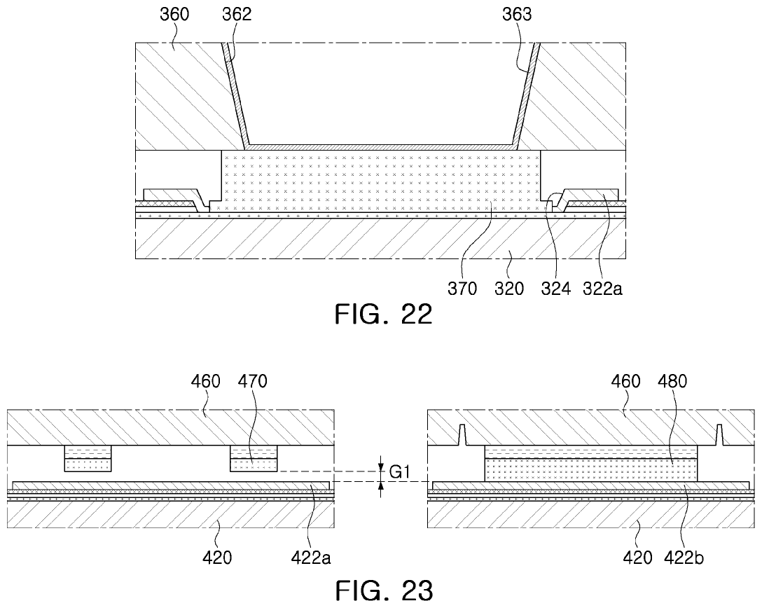

As illustrated in FIG. 21, a TSV 362 may be formed in a cap 360. As illustrated in FIG. 22, a redistribution layer 363 may be formed to extend from an internal surface of the TSV 362 to an upper surface of the cap 360.

As described above, a stepped groove 324 may be formed in the substrate 320 to reduce the pressure applied to the connection portion 370, so that the flow of the tin (Sn) layer constituting the connection portion 370 may be suppressed.

FIGS. 23 to 26 are process views illustrating a method of manufacturing a wafer level package according to one embodiment.

As illustrated in FIG. 23, a connection portion 470 and a bonding portion 480 may be formed on a cap 460. A lower surface of the cap 460 may have a planar surface. A thickness of the connection portion 470 may be greater than a thickness of the bonding portion 480. Accordingly, a lower surface of the connection portion 470 and a lower surface of the bonding portion 480 may have a height difference. The connection portion 470 may include two layers, and may include layers formed of gold (Au) and tin (Sn). An overlying layer may be formed of gold (Au), and an underlying layer may be formed of tin (Sn). The bonding portion 480 may also include two layers, and may include layers formed of gold (Au) and tin (Sn). An overlying layer may be formed of gold (Au), and an underlying layer may be formed of tin (Sn). However, examples are not limited thereto, and the connection portion 470 and the bonding portion 480 may be formed of one of copper-tin (Cu—Sn) and aluminum-germanium (Al—Ge). The connection portion 470 may include a plurality of rows, and the bonding portion 480 may include a single row. An upper surface of the first metal pad 422a, disposed below the connection portion 470, and an upper surface of the second metal pad 422b, disposed below the bonding portion 480, may be disposed on the same plane.

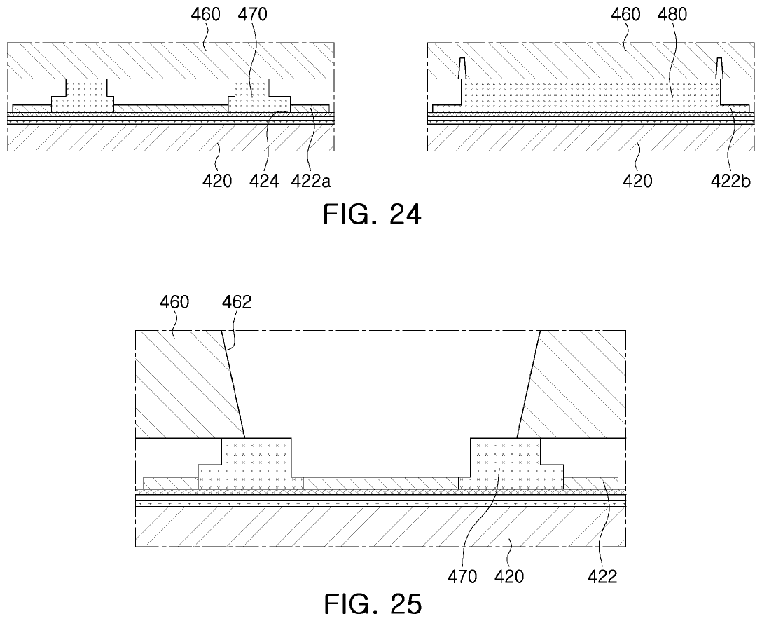

As illustrated in FIG. 24, when the substrate 420 and the cap 460 are bonded to each other, pressure applied to the connection portion 470 may be lower than pressure applied to the bonding portion 480. Accordingly, the flow of the tin (Sn) layer constituting the connection portion 470 may be suppressed. Therefore, components such as a trench and a dam to prevent the tin layer constituting the connection portion 470 from flowing toward an element portion 140 (see FIG. 1) may not be necessary. For example, the components such as a trench and a dam to prevent the tin layer from flowing toward the element portion 140 may not be formed between the connection portion 470 and the element portion 140.

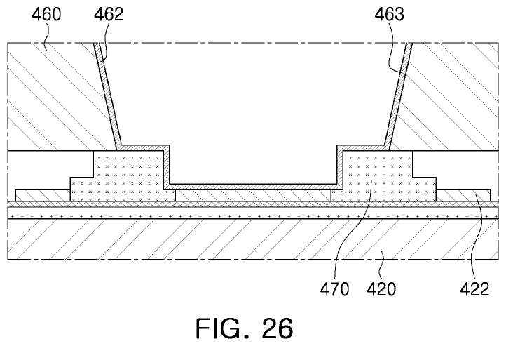

As illustrated in FIG. 25, a TSV 462 may formed n the cap 460. As illustrated in FIG. 26, a redistribution layer 463 may be formed to extend from an internal surface of the TSV 462 to an upper surface of the cap 460.

As described above, the connection portion 470 and the connection portion 480 may have different thicknesses to reduce the pressure applied to the connection portion 470, so that the flow of the tin (Sn) layer constituting the connection portion 470 may be suppressed.

As described above, a wafer level package, in which an effect caused by a flow of tin (Sn) may be reduced to achieve miniaturization of the package, and a method of manufacturing the same may be provided.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A wafer level package comprising:
a substrate;
an element portion disposed on one surface of the substrate;
a cap disposed on the substrate to cover the element portion;
a connection portion electrically connected to the element portion; and
a bonding portion disposed on an outer side of the connection portion,
wherein the bonding portion is disposed on a first surface of one of the substrate and the cap,
wherein one end portion of the connection portion is disposed on a second surface having a step difference from the first surface, and
wherein the connection portion and the bonding portion are formed of a eutectic material.

2. The wafer level package of claim 1, wherein the first surface and the second surface are disposed on the cap, the first surface is disposed on a lower surface of the cap, and the second surface is disposed on a stepped groove disposed in the cap.

3. The wafer level package of claim 2, wherein the stepped groove is connected to a through-silicon via (TSV) disposed in the cap.

4. The wafer level package of claim 2, further comprising:
an external connection terminal disposed on an upper surface of the cap and electrically connected to the connection portion; and
a passivation layer disposed to cover a redistribution layer,
wherein the external connection terminal and the connection portion are connected to each other by the redistribution layer.

5. The wafer level package of claim 1, wherein the connection portion and the bonding member are formed one of gold-tin (Au—Sn), copper-tin (Cu—Sn), or aluminum-germanium (Al—Ge), respectively.

6. The wafer level package of claim 1, wherein the cap comprises a flow suppression groove disposed between the bonding portion and the connection portion.

7. The wafer level package of claim 1, wherein the connection portion comprises a single column or a plurality of columns.

8. The wafer level package of claim 1, wherein the cap comprises a groove portion disposed over the element portion.

9. The wafer level package of claim 1, wherein the first surface and the second surface are disposed on the substrate, the first surface is disposed on an upper surface of the substrate, and the second surface is disposed on a stepped groove disposed in the substrate.

10. The wafer level package of claim 9, wherein a through-silicon via (TSV) is disposed in the cap to be disposed over the stepped groove.

11. The wafer level package of claim 9, wherein the stepped groove is disposed in a first metal pad disposed on the substrate.

12. A method of manufacturing a wafer level package comprising:
forming a connection portion and a bonding portion on a lower surface of a cap to be spaced apart from each other;
aligning a substrate, having an upper surface on which an element portion is formed, and the cap with each other; and
bonding the substrate and the cap to each other via the bonding portion,
wherein when the substrate and the cap are bonded to each other, a pressure applied to the bonding portion is higher than a pressure applied to the connection portion.

13. The method of claim 12, wherein the connection portion comprise one end portion disposed to be inserted into a stepped groove formed in the cap, and the bonding portion is disposed on a first surface disposed around the stepped groove.

14. The method of claim 13, wherein the connection portion is bonded to a first metal pad formed on an upper surface of the substrate, and the bonding portion is bonded to a second metal pad having an upper surface disposed on a same plane as an upper surface of the first metal pad.

15. The method of claim 12, wherein the connection portion comprise one end portion disposed to be inserted into a stepped groove formed in the first metal pad, and the bonding portion is disposed on an upper surface of a second metal pad having a height difference by a depth of the stepped groove.

16. The method of claim 12, wherein a thickness of the connection portion is smaller than a thickness of the bonding portion.

17. The method of claim 16, wherein the connection portion and the bonding portion are formed on a lower planar surface of the cap and an upper planar surface of the substrate, and are bonded to upper surfaces of the first and second metal pads, wherein the upper surfaces of the first and second metal pads may be disposed in a same plane.

18. The method of claim 12, wherein the connection portion and the bonding portion are formed of one of gold-tin (Au—Sn), copper-tin (Cu—Sn), or aluminum-germanium (Al—Ge), respectively.

19. A wafer level package comprising:
a substrate;
an element portion disposed on one surface of the substrate;
a cap disposed on the substrate to cover the element portion;
a connection portion electrically connected to the element portion; and
a bonding portion disposed to surround the connection portion,
wherein the bonding portion is disposed on a first surface of one of the substrate and the cap,
wherein one end portion of the connection portion is disposed on a second surface, which is recessed from the first surface, and
wherein the connection portion and the bonding portion are formed of a eutectic material.

20. The wafer level package of claim 19, wherein the second surface is connected to a through-silicon via (TSV) disposed in the cap.
